(19) United States
(12) Patent Application Publication
(10) Pub. No.: US 2024/0421092 A1
(43) Pub. Date: Dec. 19, 2024

(54) INTEGRATED THERMAL BRIDGES ON WIREBOND ASSEMBLED INTEGRATED CIRCUITS FOR HEAT SPREADING

(71) Applicant: Qorvo US, Inc., Greensboro, NC (US)

(72) Inventor: Tobias Mangold, Huglfing (DE)

(21) Appl. No.: 18/660,776

(22) Filed: May 10, 2024

Related U.S. Application Data
(60) Provisional application No. 63/472,661, filed on Jun. 13, 2023.

(51) Int. Cl. H01L 23/538; H01L 23/00; H01L 23/367

(52) U.S. Cl. CPC H01L 23/5381; H01L 23/3675; H01L 24/08; H01L 24/48; H01L 2224/08146; H01L 2224/08225; H01L 2224/48157; H01L 2224/48227; H01L 2924/10253; H01L 2924/13051; H01L 2924/13064; H01L 2924/351

(57) ABSTRACT

Embodiments of integrated circuit (IC) structures are disclosed. The IC structures include a semiconductor die mounted on a heat sink. In some embodiments, the semiconductor die includes a bulk wafer, a Front End of Line (FEOL) portion, and a Back End of Line (BEOL) portion. Active semiconductor devices are formed in the FEOL portion of the semiconductor die. The active semiconductor devices create heat. In order to increase heat flow away from an active semiconductor device, a thermally conductive bridge is formed in the BEOL portion that connects to the active semiconductor device and horizontally extends away from the active semiconductor device. The thermally conductive bridge then connects back to the semiconductor substrate at a section away from the active semiconductor device. Heat thus flows away from the active semiconductor device through the bulk wafer down to the heat sink.

### RELATED APPLICATIONS

This application claims the benefit of provisional patent application Ser. No. 63/472,661, filed Jun. 13, 2023, the disclosure of which is hereby incorporated herein by reference in its entirety.

### FIELD OF THE DISCLOSURE

The present disclosure relates to structures for dissipating heat away from active semiconductor devices in an integrated circuit (IC) structure.

### BACKGROUND

Transistors in integrated circuit (IC) structures in wire-bond (face up) assemblies, especially power devices, have to sink their dissipated power in the form of heat energy to the heat sink attached to the backside of the die. Once the heat energy has exited the chip on its backside through the die attach interface and a glue or film material fixes the chip position in the package, it's a matter of the package type to continue the heat flux path towards a background heat sink. There is a fundamental bottleneck in the heat flow semiconductor bulk material. Heat from the active semiconductor device flux enters the bulk material at a high power density and spreads out in lateral directions and vertically down the bulk material to minimize the temperature rise. However, the large power density and localization of the active semiconductor die limits how much heat can propagate through the bulk semiconductor. Thus, more efficient techniques of dissipating heat away from the active semiconductor devices are needed.

### SUMMARY

In some embodiments, an integrated circuit (IC) structure, includes a heat sink and a semiconductor substrate comprising: a bulk wafer mounted on the heat sink; a Front End of Line (FEOL) portion formed over the bulk wafer, wherein the FEOL portion includes an active semiconductor device; and a Back End of Line (BEOL) portion that includes a thermally conductive bridge, wherein the thermally conductive bridge is configured to couple to the active semiconductor device, horizontally extend away from the active semiconductor device, and then connect back to the FEOL portion on a section away from the active semiconductor device.

In some embodiments, the thermally conductive bridge includes a first vertical portion that couples to the active semiconductor device, a second vertical portion that connects back to a section of the semiconductor substrate away from the active semiconductor device, and a horizontal section that is connected between the first vertical portion and the second vertical portion. In some embodiments, the vertical section is a first vertical section and the thermally conductive bridge further includes a third vertical portion that connects back to the FEOL portion at a second section away from the active semiconductor device, wherein the section away from the active semiconductor device is a first section of the FEOL portion away from the active semiconductor device; and a second horizontal portion connected between the first vertical portion and the third vertical portion.

In some embodiments, the first horizontal portion and the second horizontal portion extend parallel to a same horizontal axis but extend in opposite directions relative to the first horizontal portion. In some embodiments, the first vertical portion includes a thermally conductive structure that connects to the active semiconductor device; the second vertical portion includes a first thermally conductive pad that attaches to the first section; and the third vertical portion includes a second thermally conductive pad that attaches to the second section.

In some embodiments, a surface area of the thermally conductive structure for connecting to the active semiconductor device is equal to less than half of a surface area of the first thermally conductive pad that attaches to the first section. In some embodiments, a surface area of the thermally conductive structure for connecting to the active semiconductor device is equal to less than half of a surface area of the second thermally conductive pad that attaches to the second section.

In some embodiments, the active semiconductor device includes conductive fingers; and the surface area of the thermally conductive structure connects to the conductive fingers. In some embodiments, the active semiconductor device is a heterojunction bipolar transistor (HBT).

In some embodiments, the HBT includes a plurality of HBT strip areas, wherein each of the strip areas are separated from one another; and the thermally conductive bridge includes: a set of first vertical portions, each of the first vertical portions attaching to a different one of the plurality of HBT strip areas; a connection portion, wherein the set of first vertical portions connects to the connection portion; a horizontally extending portion that extends horizontally away from the connection portion; and a second vertical portion that is connected to the horizontally extending portion, the second vertical portion extending vertically down to connect to the section of the FEOL portion away from the plurality of HBT strip areas.

In some embodiments, the horizontally extending portion is a first horizontally extending portion; the section is a first section of the semiconductor substrate away from the plurality of HBT strip areas; and the thermally conductive bridge further includes: a second horizontally extending portion that extends horizontally away from the connection portion in a direction along a same axis but in an opposite direction as the first horizontally extending portion; and a third vertical portion that is connected to the second horizontally extending portion, the third vertical portion extending vertically down to connect to a second section of the semiconductor substrate away from the plurality of HBT strip areas.

In some embodiments, each of the HBT strip areas of the plurality of HBT strip areas include: base fingers; and one or more emitter fingers, interleaved between the base fingers. In some embodiments, the active semiconductor device is a High Electron Mobility Transistor (HEMT). In some embodiments, the HEMT includes: a plurality of drain/source contacts; and a plurality of gate contacts interleaved between the drain/source contacts. The thermally conductive bridge includes: a set of first vertical portions, each of the first vertical portions attaching to a different one of the plurality of drain/source contacts; a connection portion, wherein the set of first vertical portions connects to the connection portion; a horizontally extending portion that extends horizontally away from the connection portion; and a second vertical portion that is connected to the horizontally extending portion, the second vertical portion extending vertically down to connect to a section of the semiconductor substrate away from the HEMT.

In some embodiments, the horizontally extending portion is a first horizontally extending portion; the section is a first section of the semiconductor substrate away from the plurality of HBT strip areas; and the thermally conductive bridge further includes: a second horizontally extending portion that extends horizontally away from the connection portion in a direction along a same axis but in an opposite direction as the first horizontally extending portion; and a second vertical portion that is connected to the second horizontally extending portion, the second vertical portion extends vertically down to connect to a second section of the semiconductor substrate away from the HEMT. In some embodiments, the IC structure further includes a package substrate, wherein the heat sink is part of the package substrate.

In some embodiments, an IC structure includes: a package substrate including a package substrate body and a metallic structure integrated into the package substrate; a semiconductor substrate, comprising: a bulk wafer attached to the metallic structure of the package substrate; an FEOL portion formed over the bulk wafer, wherein the FEOL portion includes an active semiconductor device; and a BEOL portion that includes a thermally conductive bridge, wherein the thermally conductive bridge is configured to couple to the active semiconductor device, horizontally extend away from the active semiconductor device, and then connect back to the semiconductor substrate on a section away from the active semiconductor device. In some embodiments, the section away from the active semiconductor device includes a conductive pad. In some embodiments, the FEOL portion includes an active semiconductor layer with active regions of the semiconductor device; and the conductive pad is attached to the active semiconductor layer. In some embodiments, the metallic structure includes a heat sink positioned on a surface of the package substrate body, the bulk wafer being mounted to the heat sink.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a semiconductor die, in accordance with some embodiments;

FIG. 2 is an integrated circuit (IC) package, in accordance with some embodiments;

FIG. 3 is an embodiment of an IC structure, in accordance with some embodiments;

FIG. 4 is an embodiment of an IC structure, in accordance with some embodiments;

FIG. 5 is a top view of a Front End of Line (FEOL) portion, in accordance with some embodiments;

FIG. 6A is an IC structure, in accordance with some embodiments;

FIG. 6B is a bottom perspective view of a thermally conductive bridge, in accordance with some embodiments;

FIG. 7 is a top view of an FEOL portion, in accordance with some embodiments;

FIG. 8 is an IC structure, in accordance with some embodiments; and

FIG. 9 illustrates user elements, such as mobile terminals, smart watches, tablets, computers, navigation devices, access points, and like wireless communication devices that support wireless communications, such as cellular, Wireless Local Area Network (WLAN), Bluetooth, and near field communications.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

The term “Front End of Line (FEOL) portion” refers to the portion of the semiconductor die where active semiconductor components are formed. The FEOL portion includes one or more active semiconductor layers with active regions for the active semiconductor components and at least one metal layer where contacts for the active semiconductor components are formed. FEOL processes are used to form the FEOL portion. The term “Back End of Line (BEOL) metallization” refers to the portion of a semiconductor die where interconnect layers are formed to connect different active semiconductor components and passive components in the semiconductor die and form an integrated circuit (IC). BEOL processes are used to form the BEOL portion.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

Embodiments of IC structures are disclosed. The IC structures include a semiconductor die mounted on a heat sink. In some embodiments, the semiconductor die includes a bulk wafer, a FEOL portion, and a BEOL portion. Active semiconductor devices are formed in the FEOL portion of the semiconductor die. The active semiconductor devices create heat. In order to increase heat flow away from an active semiconductor device, a thermally conductive bridge is formed that connects to the active semiconductor device and horizontally extends away from the active semiconductor device. The thermally conductive bridge then connects back to the semiconductor substrate at a section away from the active semiconductor device. Heat thus flows away from the active semiconductor device through the bulk wafer down to the heat sink.

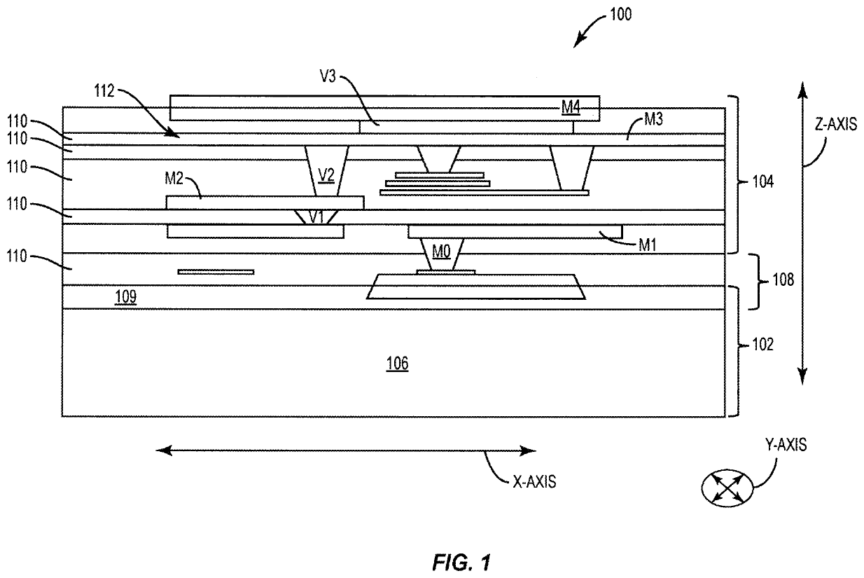

FIG. 1 is a semiconductor die 100, in accordance with some embodiments.

The semiconductor die 100 includes a semiconductor substrate 102 and a BEOL portion 104. Layers of the semiconductor die 100 are stacked relative to a Z-axis, which is considered a vertical axis. There are two horizontal axes that are both orthogonal to the Z-axis. The Y-axis is a first horizontal axis that is orthogonal to the Z-axis. In some embodiments, the Y-axis is parallel to the direction of the extension of gates or fingers formed on the semiconductor substrate 102. In FIG. 1, the Y-axis extends out of and into the page. The X-axis is another horizontal axis that is orthogonal to both the Y-axis and the Z-axis.

The semiconductor substrate 102 includes a bulk wafer 106 and an active semiconductor layer 109 formed over bulk wafer 106. The active semiconductor layer 109 is part of a FEOL portion 108. In some embodiments, there are additional intermediary layers between the active semiconductor layer 109 and the bulk wafer 106.

The bulk wafer 106 is formed from a semiconductor material such as silicon, silicon germanium (SiGe), gallium arsenic, gallium nitride, or other suitable semiconductor materials. The bulk wafer 106 provides the structural integrity of the semiconductor substrate 102 and is typically the thickest portion of the semiconductor substrate 102.

The active semiconductor layer 109 is formed from a semiconductor material such as silicon, silicon germanium (SiGe), gallium arsenic, gallium nitride, or other suitable semiconductor materials. The active semiconductor layer 109 includes active regions of active semiconductor devices, such as field effect transistors (FETs), bipolar junction transistors (BJTs), diodes, and/or the like. The active semiconductor layer 109 includes active regions that are doped either with an n-type dopant or a p-type dopant to provide the functionality necessary for active semiconductor devices.

Active semiconductor devices are formed in the FEOL portion 108. The FEOL portion 108 includes the active semiconductor layer 109 and a conductive layer M0 that is integrated into a bottom most insulating layer 110. The conductive layer M0 provides a bottom most conductive layer of a conductive structure 112 (e.g., a metallic structure 112). The conductive layer M0 includes contacts that form the contacts of the active semiconductor devices and connecting components that connect to a next highest conductive layer M1 in the conductive structure 112.

The BEOL portion 104 is formed on and over the FEOL portion 108. The remainder of the conductive structure 112 is integrated into the BEOL portion 104. From lowest to highest, the BEOL portion 104 includes conductive layers M1, M2, M3, M4. In other embodiments, there are more conductive layers and there are less conductive layers. From lowest to highest, the conductive structure 112 includes conductive via layers V1, V2, V3 between the conductive layers M1, M2, M3, M4. The conductive via layers V1, V2, V3, which include conductive vias that interconnect conductive traces, contacts, and other components in the conductive layers M1, M2, M3, M4. In this manner, the conductive structure 112 and the FEOL portion 108 form one or more integrated circuits (ICs). In this embodiment, the conductive layer M4 is the top most conductive layer of the BEOL portion 104. As such, the conductive layer M4 forms conductive components to connect to external components that are outside of the semiconductor die 100. In other embodiments, the metallic structure 112 includes only M1, M2, M3 conductive layers and conductive via layers V1, V2. In these embodiments, the conductive layer M3 forms conductive components to connect to external components that are outside of the semiconductor die 100.

Active semiconductor devices such as FETs, BJTs, diodes, and the like often generate a large amount of heat. Appropriately conducting this heat away from the active semiconductor devices allows for these devices to operate at higher frequencies and at higher voltage levels. This disclosure describes thermally conductive structures formed in the BEOL portion 104 to propagate heat out and away from the active semiconductor devices.

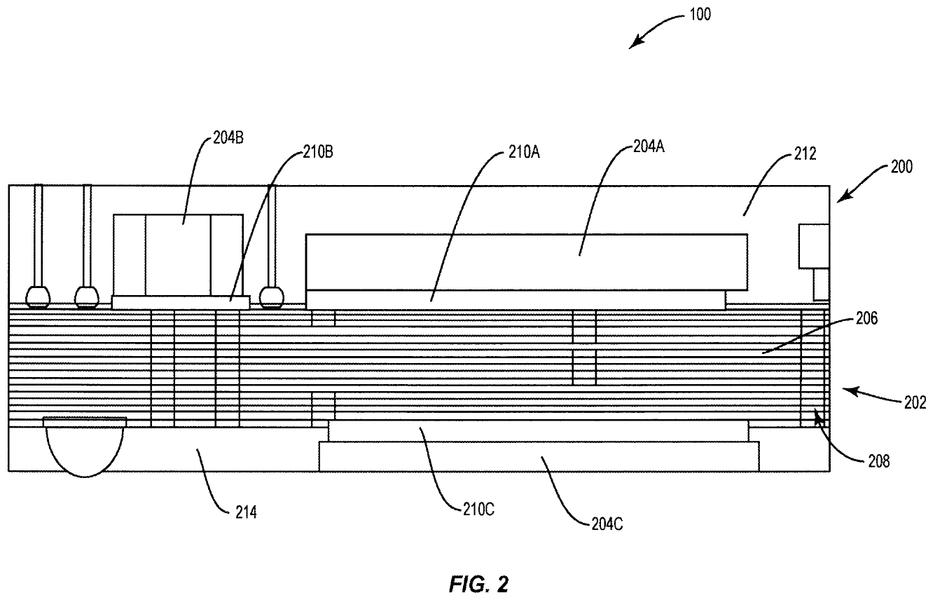

FIG. 2 is an IC package 200, in accordance with some embodiments.

In some embodiments, the IC package 200 is a double sided IC package. In particular, the IC package 200 includes a package substrate 202 and semiconductor dies 204A, 204B, 204C mounted on a top surface and on a bottom surface of the package substrate 202. More specifically, the semiconductor dies 204A, 204B are mounted on the top surface of the package substrate 202 and the semiconductor die 204C is mounted on a bottom surface of the package substrate 202.

The package substrate 202 includes a package body 206 and a conductive structure 208 (e.g., a metallic structure 208) integrated into the package body 206. The package body 206 is formed from a material such as a laminate, ceramic, and/or the like. The conductive structure 208 forms interconnections between the semiconductor dies 204A, 204B, 204C and connecting components that form connections external to the IC package 200.

In some embodiments, each of the semiconductor dies 204A, 204B, 204C is configured like the semiconductor die 100 shown in FIG. 1 or in a similar manner. In this case, the top most conductive layer in the BEOL portion (e.g., the conductive layer M4 in FIG. 1) is mounted to and forms connections with the conductive structure 208 in the package body 206. More specifically, the top most conductive layer in the BEOL portion of the semiconductor dies 204A, 204B are mounted on the top surface of the package body 206 to form connections with the conductive structure 208. The top most conductive layer in the semiconductor die 204B, 204C in the BEOL portion are mounted on the top surface of the package body 206 to form connections with the conductive structure 208. An overmold 212 is formed to surround the semiconductor dies 204A, 204B and the top surface of the package body 206. An overmold 212 is formed to surround the semiconductor die 204C and the bottom surface of the package body 206.

In some embodiments, the conductive structure 208 includes heat sinks 210A, 210B, 210C. The heat sink 210A, 210B are formed on a top surface of the package body 206 and the heat sink 210C is formed on a bottom surface of the package body 206. The bulk wafer (e.g., the bulk wafer 106 in FIG. 1) of the semiconductor die 204A is mounted on the heat sink 210A. In this manner, heat is propagated out of the semiconductor die 204A to the heat sink 210A. The bulk wafer (e.g., the bulk wafer 106 in FIG. 1) of the semiconductor die 204B is mounted on the heat sink 210B. In this manner, heat is propagated out of the semiconductor die 204B to the heat sink 210B. The bulk wafer (e.g., the bulk wafer 106 in FIG. 1) of the semiconductor die 204C connects to the heat sink 210C. In this manner, heat is propagated out of the semiconductor die 204C to the heat sink 210C.

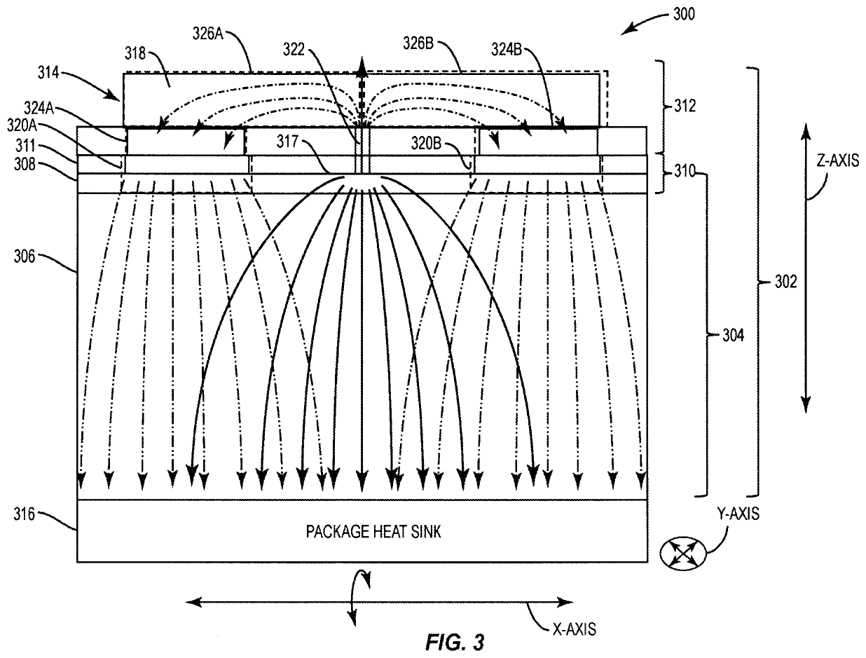

FIG. 3 is an embodiment of an IC structure 300, in accordance with some embodiments.

It should be noted that the IC structure 300 is not drawn to scale. The IC structure 300 includes a semiconductor die 302 and a heat sink 316. In some embodiments, the semiconductor die 302 is the semiconductor die 100 in FIG. 1. In some embodiments, the semiconductor die 302 is any one of the semiconductor dies 204A, 204B, 204C in FIG. 2.

The semiconductor die 302 includes a semiconductor substrate 304. In some embodiments, the semiconductor substrate 304 is provided in accordance with the semiconductor die 100 shown in FIG. 1. The semiconductor substrate 304 includes a bulk wafer 306 and an active semiconductor layer 308 formed over the bulk wafer 306. In some embodiments, the semiconductor substrate 304 is provided in accordance with the semiconductor substrate 102 shown in FIG. 1. The semiconductor die 302 further includes an FEOL portion 310. The FEOL portion 310 includes the active semiconductor layer 308 and a conductive layer 311 to form contacts for active semiconductor devices. In some embodiments, the conductive layer 311 is provided in accordance with conductive layer M0 in FIG. 1. A BEOL portion 312 is formed over the FEOL portion 310. In some embodiments, the BEOL portion 312 is provided in the same manner as the BEOL portion 104 in FIG. 1. The BEOL portion 312 includes a conductive structure 314. In some embodiments, the conductive structure 314 is provided in accordance with the conductive structure 112 shown in FIG. 1.

The semiconductor die 302 is mounted on the heat sink 316. The heat sink 316 is any one of the heat sinks 210A, 210B, 210C show in FIG. 2, in accordance with some embodiments. Accordingly, in some embodiments, the heat sink 316 is part of the conductive structure 314 (e.g., the conductive structure 208 show in FIG. 2) of the package substrate 202.

In some embodiments, the FEOL portion 310 is provided in accordance with the FEOL portion 108 shown in FIG. 1. The FEOL portion 310 includes the active semiconductor layer 308. An active semiconductor device 317 includes active regions in the active semiconductor layer 308 and one or more contacts in the conductive layer 311. The particular structure of the active semiconductor device 317 (e.g., FET, BJT, diode, etc.) depends on the particular device requirements. When the active semiconductor device 317 is operating, heat flows vertically through the semiconductor substrate 304 to the heat sink 316. However, without additional device structures, heat would accumulate along a general horizontal alignment near the active semiconductor device 317.

To ensure additional heat flow away from the active semiconductor device 317, the conductive structure 314 in the BEOL portion 312 forms a thermally conductive bridge 318. The thermally conductive bridge 318 is configured to couple to the active semiconductor device 317, horizontally extend away from the active semiconductor device 317, and then connect back to the semiconductor substrate 304 at one or more sections (in this embodiment, sections 320A, 320B) away from the active semiconductor device 317. The thermally conductive bridge 318 thus increases heat flow out of the active semiconductor device 317. In this embodiment, the thermally conductive bridge 318 connects back to the sections 320A, 320B of the semiconductor substrate 304, the sections 320A, 320B being part of the FEOL portion 310. In other embodiments, the thermally conductive bridge 318 connects back to the semiconductor substrate 304 in other ways. For example, the thermally conductive bridge 318 connects back to the semiconductor substrate 304 at other portions of the semiconductor substrate 304. For example, in some GaAs configurations, the semiconductor substrate 304 may connect back directly to the bulk wafer 306. The particular configuration shown in FIG. 3 is a flat semiconductor configuration. In other embodiments, however, the configuration may not be flat and the active semiconductor devices are formed in elevated structures on top of the bulk wafer 306, where the elevated structures do not extend across the entire top plane of the bulk wafer 306. In these cases, the thermally conductive bridge 318 may connect back to the bulk wafer 306.

In this embodiment, the thermally conductive bridge 318 includes a vertical portion 322 that couples to the active semiconductor device 317. In this embodiment, the vertical portion 322 extends relative to the Z-axis and attaches to a contact of the active semiconductor device 317 in the conductive layer 311.

The thermally conductive bridge 318 includes another a vertical portion 324A that connects back to the section 320A of the FEOL portion 310. In this embodiment, the section 320A includes a conductive pad in the conductive layer 311 and a portion of the active semiconductor layer 308 displaced from the active semiconductor device 317 relative to the X-axis. The conductive pad in the conductive layer 311 is formed on the portion of the active semiconductor layer 308 displaced from the active semiconductor device 317 relative to the X-axis. A horizontal portion 326A connects the vertical portion 322 and the vertical portion 324A. In FIG. 3, the horizontal portion 326A extends in a negative direction relative to the X-axis. In this manner, heat flows from the active semiconductor device 317, through the vertical portion 322, through the horizontal portion 326A, through the vertical portion 324A, through the section 320A, and through the bulk wafer 306 to the heat sink 316.

The thermally conductive bridge 318 includes another a vertical portion 324B that connects back to the section 320B of the FEOL portion 310. In this embodiment, the section 320B includes a conductive pad in the conductive layer 311 and a portion of the active semiconductor layer 308 displaced from the active semiconductor device 317 relative to the X-axis. The conductive pad in the conductive layer 311 is formed on the portion of the active semiconductor layer 308 displaced from the active semiconductor device 317 relative to the X-axis. A horizontal portion 326B connects the vertical portion 322 and the vertical portion 324B. In FIG. 3, the horizontal portion 326A extends in a positive direction relative to the X-axis. In this manner, heat flows from the active semiconductor device 317, through the vertical portion 322, through the horizontal portion 326B, through the vertical portion 324B, through the section 320B, and through the bulk wafer 306 to the heat sink 316.

In alternative embodiments, the thermally conductive bridge 318 includes only one of the vertical portions 324A, 324B and only one of the horizontal portions 326A, 326B, but not both. In FIG. 3, the horizontal portions 326A, 326B are formed in the top most conductive layer of the conductive structure 314 in the BEOL portion 312. In many embodiments, this is the thickest conductive layer in the BEOL portion 312 which thus increases vertical heat flow away from the active semiconductor device 317.

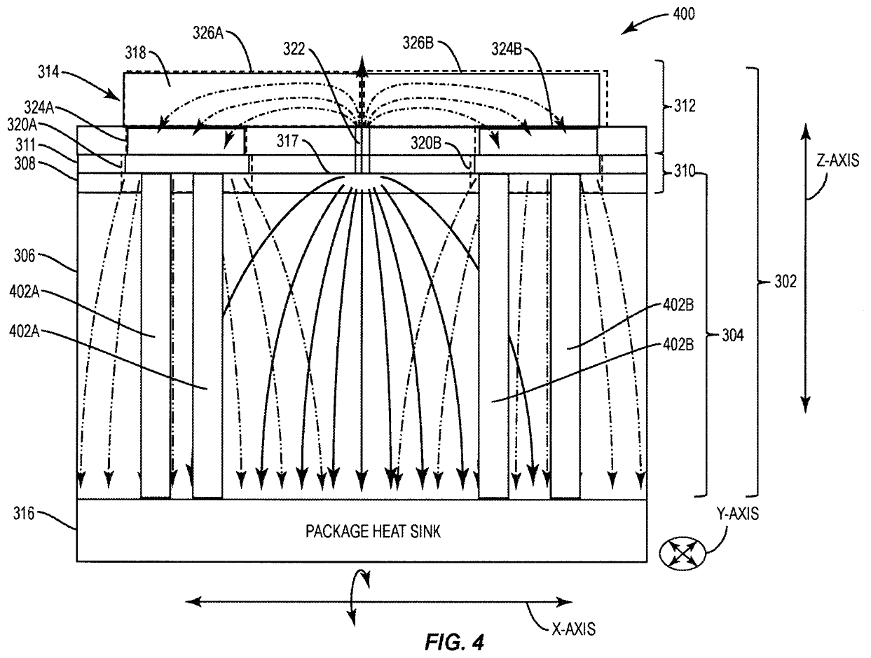

FIG. 4 is an embodiment of an IC structure 400, in accordance with some embodiments.

The IC structure 400 is the same as the IC structure 300 shown in FIG. 3, except that the IC structure 400 includes Through Bulk Vias (TBVs) 402A and TBVs 402B. The TBVs 402A extend from the conductive pad in the section 320A to the heat sink 316. In this manner, the TBVs 402A increase heat flow from the section 320A to the heat sink 316. The TBVs 402B extend from the conductive pad in the section 320B to the heat sink 316. In this manner, TBVs 402B increase heat flow from the section 320B to the heat sink 316.

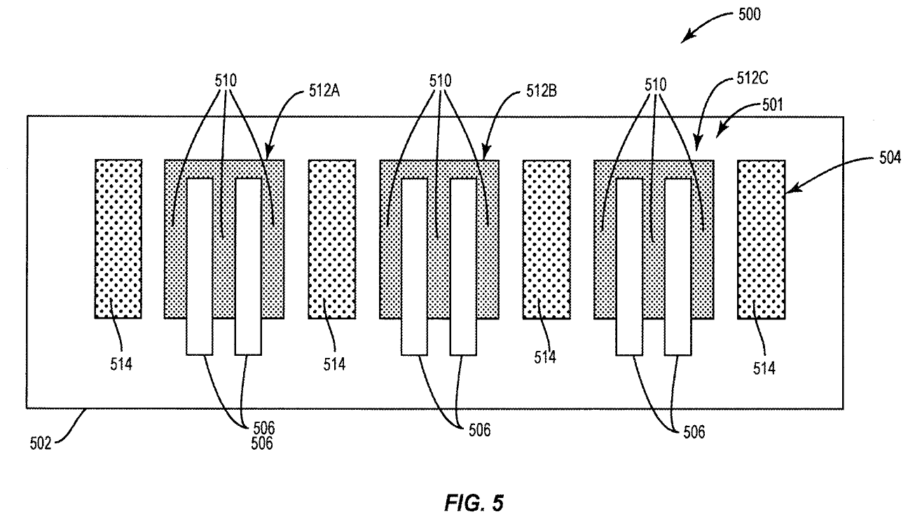

FIG. 5 illustrates a top view of an FEOL portion 500, in accordance with some embodiments.

The FEOL portion 500 includes a heterojunction bipolar transistor (HBT) 501. The FEOL portion 500 includes an active semiconductor layer 502, as discussed above, and a conductive layer 504, as discussed above. The active semiconductor layer 502 forms the active regions of the HBT 501. The conductive layer 504 forms the contacts of the HBT 501. In the conductive layer 504, the HBT 501 includes emitter fingers 506 interleaved between base fingers 510. In FIG. 5, the emitter fingers 506 interleaved between the base fingers 510 form HBT strip areas 512A, 512B, 512C. The HBT strip areas 512A, 512B, 512C are interleaved between collector contacts 514, in accordance with some embodiments. In some embodiments, there are more or HBT less strip areas. Also, in other embodiments, there are more or less emitter fingers and more or less base fingers.

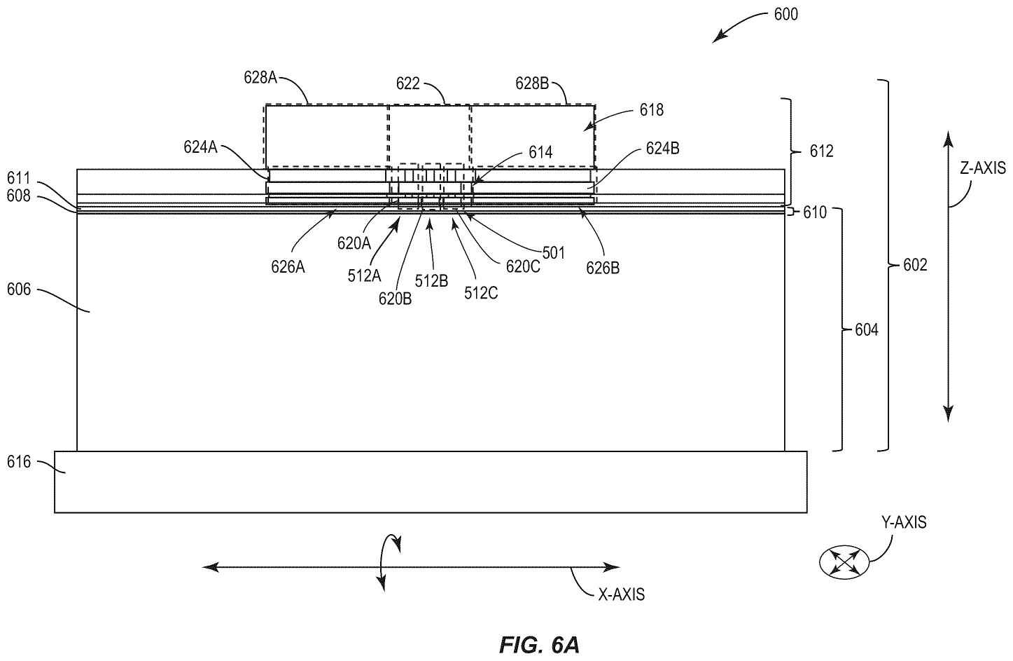

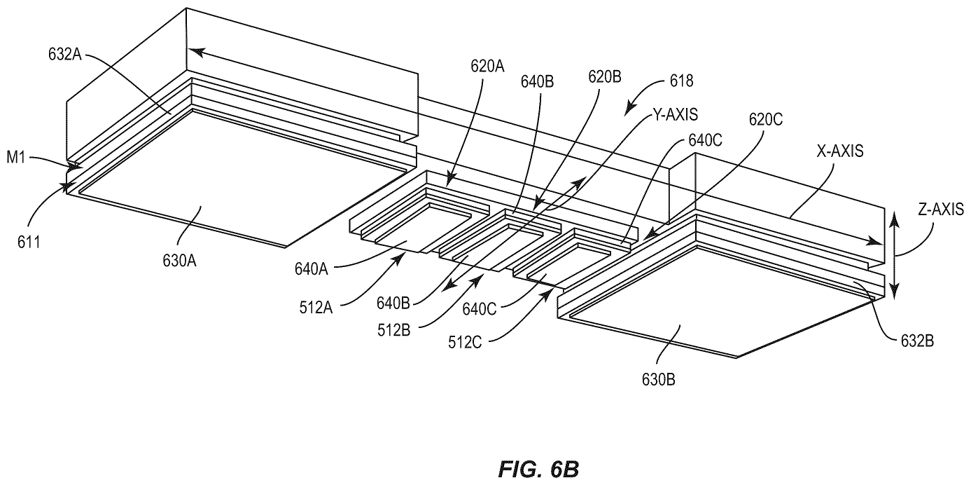

FIG. 6A is an IC structure 600, in accordance with some embodiments.

It should be noted that the IC structure 600 is not drawn to scale. The IC structure 600 includes a semiconductor die 602 and a heat sink 616. In some embodiments, the semiconductor die 602 is the semiconductor die 100 in FIG. 1. In some embodiments, the semiconductor die 602 is any one of the semiconductor dies 204A, 204B, 204C shown in FIG. 2.

The semiconductor die 602 includes a semiconductor substrate 604. In some embodiments, the semiconductor substrate 604 is provided in accordance with the semiconductor substrate 102 shown in FIG. 1. The semiconductor substrate 604 includes a bulk wafer 606 and an active semiconductor layer 608 formed over the bulk wafer 606. The semiconductor die 602 further includes an FEOL portion 610. The FEOL portion 610 includes the active semiconductor layer 608 and a conductive layer 611 to form contacts for active semiconductor devices. In this embodiment, the FEOL portion 610 includes the HBT 501 shown in FIG. 5. Thus, the FEOL portion 610 includes the HBT strip areas 512A, 512B, 512C.

In some embodiments, the conductive layer 611 is provided in accordance with conductive layer M0 in FIG. 1. A BEOL portion 612 is formed over the FEOL portion 610. In FIG. 6A, the BEOL portion 612 is provided in the same manner as the BEOL portion 104 in FIG. 1, except that the BEOL portion 612 only includes three conductive layers (M1, M2, M3 in FIG. 1) and thus only two conductive via layers (V1, V2 in FIG. 1). The BEOL portion 612 includes a conductive structure 614. In some embodiments, the conductive structure 614 is provided in accordance with the conductive structure 112 shown in FIG. 1, except the conductive structure 614 only includes three conductive layers (M1, M2, M3 in FIG. 1) and thus only two conductive via layers (V1, V2 in FIG. 1).

The semiconductor die 602 is mounted on the heat sink 616. The heat sink 616 is any one of the heat sinks 210A, 210B, 210C shown in FIG. 2, in accordance with some embodiments. Accordingly, in some embodiments, the heat sink 616 is part of the conductive structure (e.g., the conductive structure 208) of the package substrate 202 in FIG. 2.

To ensure additional heat flow away from the HBT 501, the conductive structure 614 in the BEOL portion 612 forms a thermally conductive bridge 618. The thermally conductive bridge 618 includes a vertical portion 620A that connects to the HBT strip area 512A. The thermally conductive bridge 618 further includes a connection portion 622. The vertical portion 620A also connects to the connection portion 622. Thus, the vertical portion 620A extends from the HBT strip area 512A to the connection portion 622. In this manner, heat flows from the HBT strip area 512A up through the vertical portion 620A and into the connection portion 622.

The thermally conductive bridge 618 includes a vertical portion 620B that connects to the HBT strip area 512B. The vertical portion 620B also connects to the connection portion 622. Thus, the vertical portion 620B extends from the HBT strip area 512B to the connection portion 622. In this manner, heat flows from the HBT strip area 512B up through the vertical portion 620B and into the connection portion 622.

The thermally conductive bridge 618 includes a vertical portion 620C that connects to the HBT strip area 512C. The vertical portion 620C also connects to the connection portion 622. Thus, the vertical portion 620C extends from the HBT strip area 512C to the connection portion 622. In this manner, heat flows from the HBT strip area 512C up through the vertical portion 620C and into the connection portion 622.

The thermally conductive bridge 618 includes a vertical portion 624A that connects to a section 626A of the FEOL portion 610. The section 626A is displaced from the HBT strip areas 512A, 512B, 512C with respect to the X-axis in a negative direction. The section 626A includes a conductive pad in the conductive layer 611 that is attached to a portion of the active semiconductor layer 608. A horizontal portion 628A connects the connection portion 622 to the vertical portion 624A. In FIG. 6A, the horizontal portion 628A extends in a negative direction relative to the X-axis with respect to the connection portion 622. As such, heat flows from the connection portion 622, through the horizontal portion 628A, through the vertical portion 624A, through the section 626A, and through the bulk wafer 606 to the heat sink 616.

The thermally conductive bridge 618 includes a vertical portion 624B that connects to a section 626B of the FEOL portion 610. The section 626B is displaced from the HBT strip areas 512A, 512B, 512C with respect to the X-axis in a positive direction. The section 626B includes a conductive pad in the conductive layer 611 that is attached to a portion of the active semiconductor layer 608. A horizontal portion 628B connects the connection portion 622 to the vertical portion 624B. In FIG. 6A, the horizontal portion 628A extends in a positive direction relative to the X-axis with respect to the connection portion 622. As such, heat flows from the connection portion 622, through the horizontal portion 628B, through the vertical portion 624B, through the section 626B, and through the bulk wafer 606 to the heat sink 616.

FIG. 6B is a bottom perspective view of the thermally conductive bridge 618, in accordance with some embodiments.

FIG. 6B shows thermally conductive pads 630A, 630B in the conductive layer 611. The thermally conductive pads 630A, 630B are attached to thermally conductive pads 632A, 632B in the conductive layer M1 of the BEOL portion 612 from FIG. 6A. The thermally conductive pads 630A, 630B have the same surface area with respect to the X-axis and the Y-axis as the thermally conductive pads 632A, 632B.

FIG. 6B also shows the HBT strip areas 512A, 512B, 512C. The HBT strip area 512A is connected to a conductive pad 640A in the conductive layer M1 at the bottom of the vertical portion 620A. The HBT strip area 512B is connected to a conductive pad 640B in the conductive layer M1 at the bottom of the vertical portion 620B. The HBT strip area 512C is connected to a conductive pad 640C in the conductive layer M1 at the bottom of the vertical portion 620C.

The surface area of the conductive pads 640A, 640B, 640C (both individually and in combination) is at least less than half the surface area of the thermally conductive pad 632A. Additionally, the surface area of the conductive pads 640A, 640B, 640C (both individually and in combination) is at least less than half the surface area of the thermally conductive pad 632B. This permits heat to spread out into the thermally conductive pads 630A, 630B to increase heat flow.

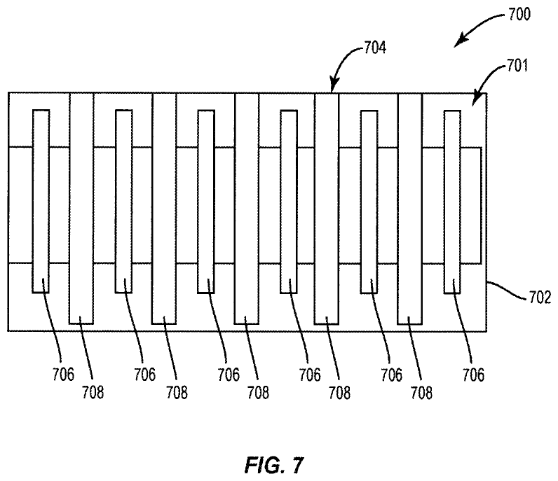

FIG. 7 illustrates a top view of an FEOL portion 700, in accordance with some embodiments.

The FEOL portion 700 includes a High Electron Mobility Transistor (HEMT) 701. The FEOL portion 700 includes an active semiconductor layer 702, as discussed above, and a conductive layer 704, as discussed above. The active semiconductor layer 702 forms the active regions of the HEMT 701. The conductive layer 704 forms the contacts of the HEMT 701. In the conductive layer 704, the HEMT 701 includes gate contacts 708 and interleaved drain source contacts 706. This array of gate contacts 708 and interleaved drain source contacts 706 may have any number of gate contacts 708 and interleaved drain source contacts 706 depending on the functional specifications of the HEMT 701.

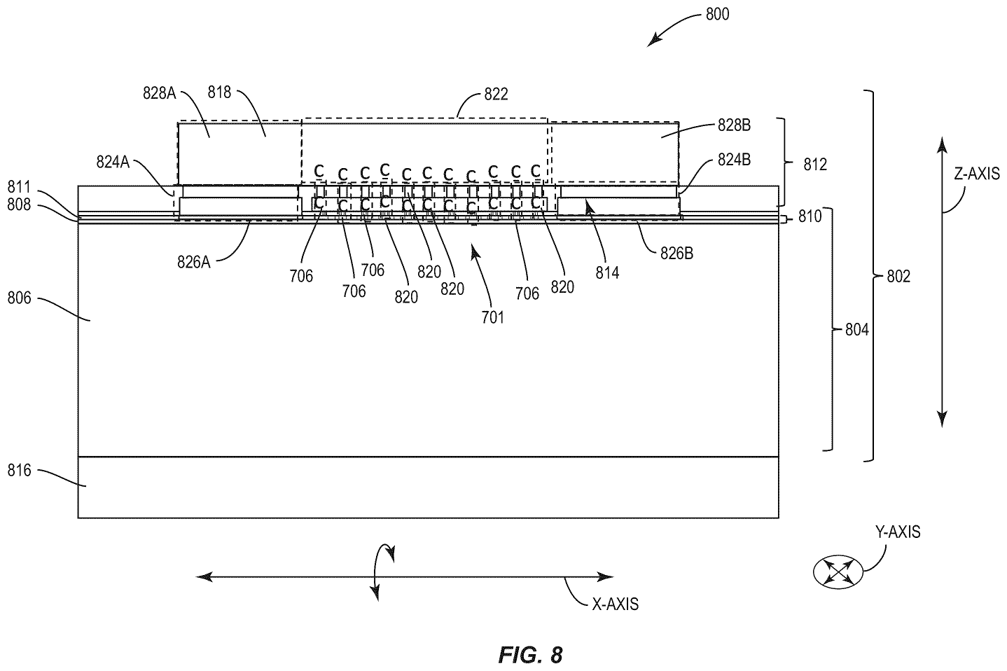

FIG. 8 is an IC structure 800, in accordance with some embodiments.

It should be noted that the IC structure 800 is not drawn to scale. The IC structure 800 includes a semiconductor die 802 and a heat sink 816. In some embodiments, the semiconductor die 802 is the semiconductor die 100 in FIG. 1. In some embodiments, the semiconductor die 802 is any one of the semiconductor dies 204A, 204B, 204C shown in FIG. 2.

The semiconductor die 802 includes a semiconductor substrate 804. In some embodiments, the semiconductor substrate 804 is provided in accordance with the semiconductor substrate 102 shown in FIG. 1. The semiconductor substrate 804 includes a bulk wafer 806 and an active semiconductor layer 808 formed over the bulk wafer 806. The semiconductor die 802 further includes an FEOL portion 810. The FEOL portion 810 includes the active semiconductor layer 808 and a conductive layer 811 to form contacts for active semiconductor devices. In this embodiment, the FEOL portion 810 includes the HEMT 701 shown in FIG. 7. Thus, the FEOL portion 810 includes the interleaved drain source contacts 706 show in FIG. 7 (not all labeled in FIG. 8, for the sake of clarity and brevity).

In some embodiments, the conductive layer 811 is provided in accordance with conductive layer M0 in FIG. 1. A BEOL portion 812 is formed over the FEOL portion 810. In FIG. 8, the BEOL portion 812 is provided in the same manner as the BEOL portion 104 in FIG. 1, except that the BEOL portion 812 only includes three conductive layers (M1, M2, M3 in FIG. 1) and thus only two conductive via layers (V1, V2 in FIG. 1). The BEOL portion 812 includes a conductive structure 814. In some embodiments, the conductive structure 814 is provided in accordance with the conductive structure 112 shown in FIG. 1, except the conductive structure 814 only includes three conductive layers (M1, M2, M3 in FIG. 1) and thus only two conductive via layers (V1, V2 in FIG. 1).

The semiconductor die 802 is mounted on the heat sink 816. The heat sink 816 is any one of the heat sinks 210A, 210B, 210C show in FIG. 2, in accordance with some embodiments. Accordingly, in some embodiments, the heat sink 816 is part of the conductive structure 814 (e.g., the conductive structure 216 in FIG. 2) of the package substrate 202 in FIG. 2.

To ensure additional heat flow away from the HEMT 701, the conductive structure 814 in the BEOL portion 812 forms a thermally conductive bridge 818. The thermally conductive bridge 818 includes vertical portions 820 (not all labeled, for the sake of clarity and brevity). The thermally conductive bridge 818 further includes a connection portion 822. At one of their ends, each of the vertical portions 820 is connected to the connection portion 822. At another one of the ends, each of the vertical portions 820 connects to a different one of the interleaved drain source contacts 706. Thus, the vertical portions 820 extend from a particular one of the interleaved drain source contacts 706 to the connection portion 822. In this manner, heat flows from the interleaved drain source contacts 706 up through the vertical portions 820 and into the connection portion 822.

The thermally conductive bridge 818 includes a vertical portion 824A that connects to a section 826A of the FEOL portion 810. The section 826A is displaced from the HEMT 701 with respect to the X-axis in a negative direction. The section 826A includes a conductive pad in the conductive layer 811 that is attached to a portion of the active semiconductor layer 808. A horizontal portion 828A connects the connection portion 822 to the vertical portion 824A. In FIG. 8, the horizontal portion 828A extends in a negative direction relative to the X-axis with respect to the connection portion 822. As such, heat flows from the connection portion 822, through the horizontal portion 828A, through the vertical portion 824A, through the section 826A, and through the bulk wafer 806 to the heat sink 816.

The thermally conductive bridge 818 includes a vertical portion 824B that connects to a section 826B of the FEOL portion 810. The section 826B is displaced from the HEMT 701 with respect to the X-axis in a positive direction. The section 826B includes a conductive pad in the conductive layer 811 that is attached to a portion of the active semiconductor layer 808. A horizontal portion 828B connects the connection portion 822 to the vertical portion 824B. In FIG. 8, the horizontal portion 828B extends in a positive direction relative to the X-axis with respect to the connection portion 822. As such, heat flows from the connection portion 822, through the horizontal portion 828B, through the vertical portion 824B, through the section 826B, and through the bulk wafer 806 to the heat sink 816.

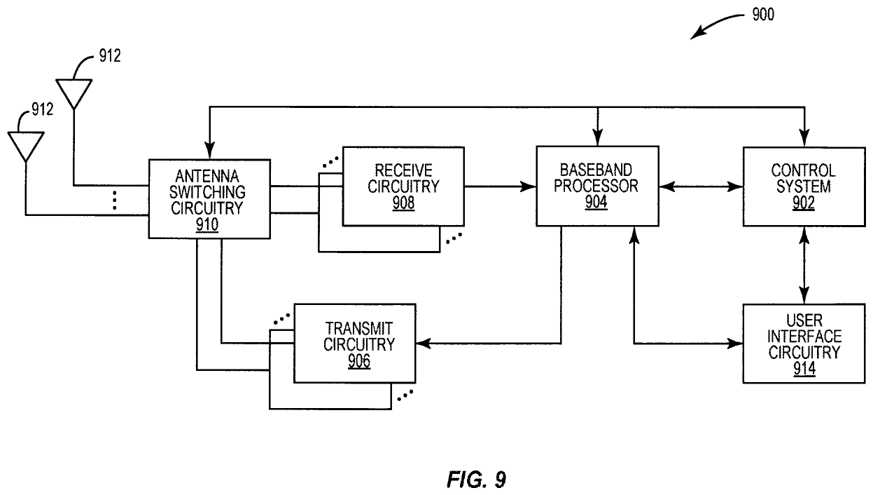

With reference to FIG. 9, the concepts described above may be implemented in various types of user elements 900, such as mobile terminals, smart watches, tablets, computers, navigation devices, access points, and like wireless communication devices that support wireless communications, such as cellular, wireless local area network (WLAN), Bluetooth, and near field communications.

The concepts described above may be used in IC packages of the user elements 900. The user elements 900 will generally include a control system 902, a baseband processor 904, transmit circuitry 906, receive circuitry 908, antenna switching circuitry 910, multiple antennas 912, and user interface circuitry 914. In a non-limiting example, the control system 902 may be a field-programmable gate array (FPGA) or an application-specific integrated circuit (ASIC). In this regard, the control system 902 may include at least a microprocessor(s), an embedded memory circuit(s), and a communication bus interface(s). The receive circuitry 908 receives radio frequency signals via the antennas 912 and through the antenna switching circuitry 910 from one or more base stations. A low noise amplifier and a filter cooperate to amplify and remove broadband interference from the received signal for processing.

Downconversion and digitization circuitry (not shown) will then downconvert the filtered, received signal to an intermediate or baseband frequency signal, which is then digitized into one or more digital streams using analog-to-digital converter(s) (ADC).

The baseband processor 904 processes the digitized received signal to extract the information or data bits conveyed in the received signal. This processing typically comprises demodulation, decoding, and error correction operations, as will be discussed in greater detail below. The baseband processor 904 is generally implemented in one or more digital signal processors (DSPs) and application specific integrated circuits (ASICs).

For transmission, the baseband processor 904 receives digitized data, which may represent voice, data, or control information, from the control system 902, which it encodes for transmission. The encoded data is output to the transmit circuitry 906, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 912 through the antenna switching circuitry 910. The multiple antennas 912 and the replicated transmit and receive the circuitries 906, 908 may provide spatial diversity. Modulation and processing details will be understood by those skilled in the art.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. An integrated circuit (IC) structure, comprising:
a heat sink;
a semiconductor substrate, comprising:
a bulk wafer mounted on the heat sink; and
a Front End of Line (FEOL) portion formed over the bulk wafer, wherein the FEOL portion includes an active semiconductor device; and
a Back End of Line (BEOL) portion that comprises a thermally conductive bridge, wherein the thermally conductive bridge is configured to couple to the active semiconductor device, horizontally extend away from the active semiconductor device, and then connect back to the semiconductor substrate on a section away from the active semiconductor device.

2. The IC structure of claim 1, wherein the thermally conductive bridge comprises a first vertical portion that couples to the active semiconductor device, a second vertical portion that connects back to the section of the semiconductor substrate away from the active semiconductor device, a horizontal section that is connected between the first vertical portion and the second vertical portion.

3. The IC structure of claim 2, wherein the thermally conductive bridge further comprises:
a third vertical portion that connects back to the semiconductor substrate at a second section away from the active semiconductor device, wherein the section away from the active semiconductor device is a first section of the semiconductor substrate away from the active semiconductor device; and
a second horizontal section connected between the first vertical portion and the third vertical portion.

4. The IC structure of claim 3, wherein the horizontal section and the second horizontal section extend parallel to a same horizontal axis but extend in opposite directions relative to the horizontal section.

5. The IC structure of claim 3, wherein:
the first vertical portion includes a thermally conductive structure that connects to the active semiconductor device;
the second vertical portion includes a first thermally conductive pad that attaches to the first section; and
the third vertical portion includes a second thermally conductive pad that attaches to the second section.

6. The IC structure of claim 5, wherein a surface area of the thermally conductive structure for connecting to the active semiconductor device is equal to less than half of a surface area of the first thermally conductive pad that attaches to the first section.

7. The IC structure of claim 6, wherein the surface area of the thermally conductive structure for connecting to the active semiconductor device is equal to less than half of a surface area of the second thermally conductive pad that attaches to the second section.

8. The IC structure of claim 7, wherein:
the active semiconductor device comprises conductive fingers; and
the surface area of the thermally conductive structure connects to the conductive fingers.

9. The IC structure of claim 1, wherein the active semiconductor device is a heterojunction bipolar transistor (HBT).

10. The IC structure of claim 9, wherein:
the HBT comprises of a plurality of HBT strip areas, wherein each of the HBT strip areas are separated from one another; and
the thermally conductive bridge comprises:
a set of first vertical portions, each of the first vertical portions attaching to a different one of the plurality of HBT strip areas;
a connection portion, wherein the set of first vertical portions connects to the connection portion;
a horizontally extending portion that extends horizontally away from the connection portion; and
a second vertical portion that is connected to the horizontally extending portion, the second vertical portion extending vertically down to connect to a section of the semiconductor substrate away from the plurality of HBT strip areas.

11. The IC structure of claim 10, wherein:
the horizontally extending portion is a first horizontally extending portion;
the section is a first section of the semiconductor substrate away from the plurality of HBT strip areas; and
the thermally conductive bridge further comprises:
a second horizontally extending portion that extends horizontally away from the connection portion in a direction along a same axis but in an opposite direction as the first horizontally extending portion; and
a third vertical portion that is connected to the second horizontally extending portion, the third vertical portion extending vertically down to connect to a second section of the semiconductor substrate away from the plurality of HBT strip areas.

12. The IC structure of claim 10, wherein each of the HBT strip areas of the plurality of HBT strip areas comprises:
base fingers; and
one or more emitter fingers, interleaved between the base fingers.

13. The IC structure of claim 10, wherein:
the horizontally extending portion is a first horizontally extending portion;
the section is a first section of the semiconductor substrate away from the plurality of HBT strip areas; and
the thermally conductive bridge further comprises:
a second horizontally extending portion that extends horizontally away from the connection portion in a direction along a same axis but in an opposite direction as the first horizontally extending portion; and
a second vertical portion that is connected to the second horizontally extending portion, the second vertical portion extends vertically down to connect to a second section of the semiconductor substrate away from the High Electron Mobility Transistor (HEMT).

14. The IC structure of claim 1, wherein the active semiconductor device is a High Electron Mobility Transistor (HEMT).

15. The IC structure of claim 14, wherein the HEMT comprises:
a plurality of drain/source contacts;
a plurality of gate contacts interleaved between the plurality of drain/source contacts; and
the thermally conductive bridge comprises:
a set of first vertical portions, each of the first vertical portions attaching to a different one of the plurality of drain/source contacts;
a connection portion, wherein the set of first vertical portions connects to the connection portion;
a horizontally extending portion that extends horizontally away from the connection portion; and
a second vertical portion that is connected to the horizontally extending portion, the second vertical portion extending vertically down to connect to a section of the semiconductor substrate away from the HEMT.

16. The IC structure of claim 1, further comprising:
a package substrate, wherein the heat sink is part of the package substrate.

17. An integrated circuit (IC) structure, comprising:
a package substrate including a package substrate body and a metallic structure integrated into the package substrate;
a semiconductor substrate, comprising:
a bulk wafer attached to the metallic structure of the package substrate; and
a Front End of Line (FEOL) portion formed over the bulk wafer, wherein the FEOL portion includes an active semiconductor device; and
a Back End of Line (BEOL) portion that comprises a thermally conductive bridge, wherein the thermally conductive bridge is configured to couple to the active semiconductor device, horizontally extend away from the active semiconductor device, and then connect back to the semiconductor substrate on a section away from the active semiconductor device.

18. The IC structure of claim 17, wherein the section away from the active semiconductor device comprises a conductive pad.

19. The IC structure of claim 17, wherein:
the semiconductor substrate comprises an active semiconductor layer with active regions of the active semiconductor device; and
a conductive pad is attached to the active semiconductor layer.

20. The IC structure of claim 17, wherein the metallic structure includes a heat sink positioned on a surface of the package substrate body, the bulk wafer being mounted to the heat sink.
